(19) United States
(12) Patent Application Publication
(10) Pub. No.: US 2025/0219393 A1
(43) Pub. Date: Jul. 3, 2025

(54) TIME SEQUENCE PROTECTION CIRCUIT, ELECTRONIC DEVICE AND METHOD FOR CONTROLLING CONTROLLED CIRCUIT

(71) Applicant: NOKIA SOLUTIONS AND NETWORKS OY, Espoo (FI)

(72) Inventors: Xiaohui ZHU, Hangzhou, Zhejiang (CN); Lei YAO, Hangzhou, Zhejiang (CN); Weiqiang YING, Hangzhou, Zhejiang (CN); Zhenyin ZHANG, Hangzhou, Zhejiang (CN)

(21) Appl. No.: 18/850,756

(22) PCT Filed: Apr. 1, 2022
(86) PCT No.: PCT/CN2022/084801

§ 371 Date: Sep. 25, 2024

(51) Int. Cl. H02H 7/10; H02H 1/04; H02M 1/36

(52) U.S. Cl. CPC H02H 7/10; H02H 1/043; H02M 1/36

(57) ABSTRACT

According to embodiments of the present disclosure. there is provided a time sequence protection circuit. The time sequence protection circuit comprises a first resistor coupled to a positive input pin; a first diode having an anode terminal coupled to the first resistor at a first node and a cathode terminal coupled to a second node: a capacitor coupled between the second node and a negative input pin; a second diode having an anode terminal coupled to the first node and a cathode terminal coupled to an output pin; a third diode having an anode terminal coupled to the output pin and a cathode terminal coupled to the positive input pin; and at least one of: a fourth diode having an anode terminal coupled to the second node and a cathode terminal coupled to the positive input pin, and a second resistor coupled between the second node and the negative input pin. Such arrangement enables slow turning-on and fast turning-off of the controlled circuit and can also resist interference.

### FIELD

Embodiments of the present disclosure relate generally to time sequence protection circuits, electronic devices comprising the same and methods for controlling a controlled circuit utilizing a time sequence protection module.

### BACKGROUND

In the field of electronic devices, reliable turning-on and turning-off operations of an electronic device are very important for its secure and stable working in the long term. For example, in order to avoid damage to a power supply unit (PSU) at the start-up stage, a control circuit for slow turning-on of the power converter in the PSU may be provided to avoid incorrect early turning-on of the power converter. However, such arrangement may result in slow turning-off of the power converter, and thus cannot provide effective protection to the PSU in abnormal conditions.

Therefore, there is a need for further improvements to better control electronic devices utilizing a time sequence protection circuit.

### SUMMARY

According to embodiments of the present disclosure, there is provided a solution for better controlling electronic devices utilizing a time sequence protection circuit.

In a first aspect, there is provided a time sequence protection circuit. The time sequence protection circuit comprises a first resistor coupled to a positive input pin of the time sequence protection circuit; a first diode having an anode terminal coupled to the first resistor at a first node and a cathode terminal coupled to a second node; a capacitor coupled between the second node and a negative input pin of the time sequence protection circuit; a second diode having an anode terminal coupled to the first node and a cathode terminal coupled to an output pin of the time sequence protection circuit; and a third diode having an anode terminal coupled to the output pin and a cathode terminal coupled to the positive input pin; wherein the time sequence protection circuit further comprises at least one of: a fourth diode having an anode terminal coupled to the second node and a cathode terminal coupled to the positive input pin; and a second resistor coupled between the second node and the negative input pin.

In a second aspect, there is provided an electronic device. The electronic device comprises a controlled circuit configured to be power supplied by an input voltage the time sequence protection circuit according to embodiments of the first aspect, and a driving control circuit. The time sequence protection circuit is configured to generate a processed enable signal at the output pin based on an enable signal, wherein the enable signal is a time sequence signal indicative of turn-on/turn-off operations to be performed on the controlled circuit. The driving control circuit is configured to start the controlled circuit to work or shut the controlled circuit down based on the processed enable signal.

In a third aspect, there is provided a method for controlling a controlled circuit utilizing a time sequence protection module, wherein the time sequence protection module comprises a first resistor coupled to a positive input pin of the time sequence protection module; a first diode having an anode terminal coupled to the first resistor at a first node and a cathode terminal coupled to a second node; a capacitor coupled between the second node and a negative input pin of the time sequence protection module; a second diode having an anode terminal coupled to the first node and a cathode terminal coupled to an output pin of the time sequence protection module; and a third diode having an anode terminal coupled to the output pin and a cathode terminal coupled to the positive input pin. The method comprises in response to an increase in potential difference between the positive input pin and the negative input pin, charging the capacitor by a first current path from the positive input pin through the first resistor and the first diode to the capacitor; and in response to a potential difference between the first node and the output pin reaching a threshold voltage of the second diode, generating an output signal for controlling the controlled circuit at the output pin by a second current path from the positive input pin through the first resistor and the second diode to the output pin. The method further comprises, in response to the potential difference between the positive input pin and the negative input pin decreasing to zero, decreasing the output signal by providing a third current path from the output pin through the third diode to the positive input pin; and discharging the capacitor by at least one of: a fourth current path from the capacitor through a fourth diode to the positive input pin and a fifth current path from the capacitor through a second resistor to the negative input pin. The fourth diode has an anode terminal coupled to the second node and a cathode terminal coupled to the positive input pin. The second resistor is between the second node and the negative input pin.

The Summary is to introduce a selection of concepts in a simplified form that are further described below in the Detailed Description. The Summary is not intended to identify key features or essential features of the present disclosure, nor is it intended to be used to limit the scope of the present disclosure.

### BRIEF DESCRIPTION OF THE DRAWINGS

Through the following detailed descriptions with reference to the accompanying drawings, the above and other objectives, features and advantages of the example embodiments disclosed herein will become more comprehensible. In the drawings, several example embodiments disclosed herein will be illustrated in an example and in a non-limiting manner, where:

FIG. 1 illustrates an example environment in which a control circuit comprising a time sequence protection circuit in accordance with an embodiment of the present disclosure can be implemented;

FIG. 2 illustrates an example block diagram of an electronic device comprising an time sequence protection circuit in accordance with an embodiment of the present disclosure;

FIG. 3 illustrates an example circuit implementation of a time sequence protection circuit in accordance with a first embodiment of the present disclosure;

FIG. 4 illustrates an example circuit implementation of a time sequence protection circuit in accordance with a second embodiment of the present disclosure;

FIG. 5 illustrates an example circuit implementation of a time sequence protection circuit in accordance with a third embodiment of the present disclosure;

FIG. 6 illustrates graphical representations of measured waveforms of the input and output signals of the time sequence protection circuit in accordance with an embodiment of the present disclosure;

FIG. 7A illustrates graphical representations of measured waveforms of the output signal of the time sequence protection circuit in FIG. 5 without the second diode when interference occurs to the input signal;

FIG. 7B illustrates an enlarged plot of measured waveforms in region A in FIG. 7A;

FIG. 7C illustrates graphical representations of measured waveforms of the output signal of the time sequence protection circuit in FIG. 5 when interference occurs to the input signal;

FIG. 7D illustrates an enlarged plot of measured waveforms in region B in FIG. 7C; and

FIG. 8 illustrates a flow diagram of a method for controlling a controlled circuit utilizing a time sequence protection module in accordance with an embodiment of the present disclosure.

Throughout the drawings, the same or similar reference symbols refer to the same or similar elements.

### DETAILED DESCRIPTION OF EMBODIMENTS

Principles of the present disclosure will now be described with reference to some example embodiments. It is to be understood that these embodiments are described only for the purpose of illustration and help those skilled in the art to better understand and thus implement the present disclosure, without suggesting any limitations to the scope of the subject matter disclosed herein.

As used herein, the term “includes” and its variants are to be read as open terms that mean “includes, but is not limited to.” The term “based on” is to be read as “based at least in part on.” The terms “an implementation” and “one implementation” are to be read as “at least one implementation.” The term “another implementation” is to be read as “at least one other implementation.” The term “first,” “second,” and the like may refer to different or the same objects. Other definitions, either explicit or implicit, may be included below. A definition of a term is consistent throughout the description unless the context clearly indicates otherwise.

As briefly mentioned above, reliable turning-on and turning-off operations of an electronic device are very important for its secure and stable working in the long term. For example, in the field of PSU comprising a power converter, a large inrush current may be generated due to charging of the filter capacitor at the front end of the power converter when a PSU is started up. An inrush protection MOSFET may be provided to limit the inrush current. However, the inrush protection MOSFET may be easily damaged if the power converter in the PSU is turned on early incorrectly. Conventional control circuits may be provided with a delay module to enable turning-on of the power converter after a delay time from the start-up of the PSU. However, such delay module also results in slow turning-off of the power converter, which might cause damage to the PSU and load when an abnormal condition occurs. It is to be understood that the PSU is only for the purpose of illustration, without suggesting any limitation to functions and the scope of the embodiments of the present disclosure.

Embodiments of the present disclosure provide a time sequence protection circuit. The time sequence protection circuit comprises a first resistor coupled to a positive input pin of the time sequence protection circuit; a first diode having an anode terminal coupled to the first resistor at a first node and a cathode terminal coupled to a second node; a capacitor coupled between the second node and a negative input pin of the time sequence protection circuit; a second diode having an anode terminal coupled to the first node and a cathode terminal coupled to an output pin of the time sequence protection circuit; and a third diode having an anode terminal coupled to the output pin and a cathode terminal coupled to the positive input pin; wherein the time sequence protection circuit further comprises at least one of: a fourth diode having an anode terminal coupled to the second node and a cathode terminal coupled to the positive input pin; and a second resistor coupled between the second node and the negative input pin.

It is to be understood that the time sequence protection circuit can be used in various electronic devices which are to be turned on and off according to a time sequence signal, and is not limited to field of PSU. As used herein, the term “time sequence protection circuit” may output a voltage signal for controlling a controlled circuit, based on an input time sequence signal indicative of turn-on/turn-off operations to be performed on the controlled circuit. The output voltage signal may be output stably regardless of the elapsed time period from a transition edge of the input time sequence signal.

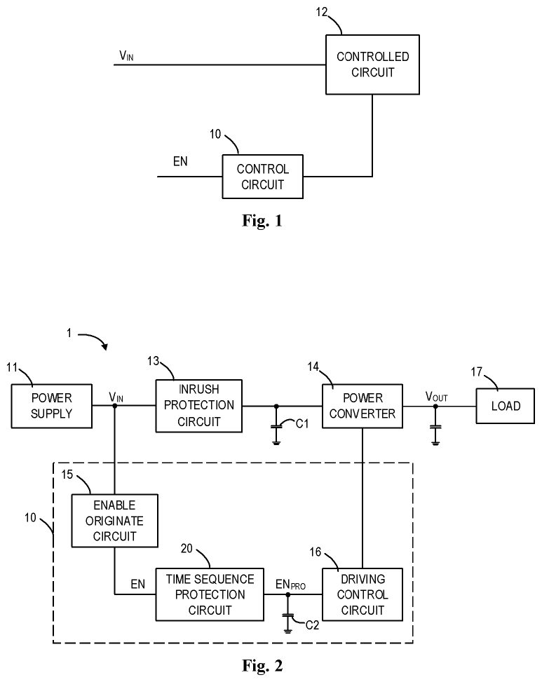

Example embodiments of the present disclosure will be discussed in detail below with reference to FIGS. 1-7D. FIG. 1 illustrates an example environment in which a control circuit comprising a time sequence protection circuit in accordance with an embodiment of the present disclosure can be implemented. It is to be understood that the environment shown in FIG. 1 is only for the purpose of illustration, without suggesting any limitation to functions and the scope of the embodiments of the present disclosure.

In FIG. 1, a controlled circuit 12 may be configured to be power supplied by an input voltage V_{IN}. In an embodiment, the controlled circuit 12 may include a power converter for converting the input voltage V_{IN} into an output voltage V_{OUT}. A control circuit 10 comprising a time sequence protection circuit may be configured to control operation states of the controlled circuit 12 in response to receiving an enable signal EN. The enable signal EN may be a time sequence signal indicative of turning-on/turning-off operations to be performed on the controlled circuit 12.

FIG. 2 illustrates an example block diagram of an electronic device 1 comprising a time sequence protection circuit 20 in accordance with an embodiment of the present disclosure.

The electronic device 1 may include a control circuit 10 and a power converter 14 as a controlled circuit. The power converter 14 may be configured to convert the input voltage V_{IN} provided by the power supply 11 into an output voltage V_{OUT} for supplying power to the load 17. When the power supply 11 is powered up, a large inrush current may be generated due to charging of the filter capacitor C1 at the front end of the power converter 14. In an embodiment, an inrush protection circuit 13 may be configured to limit the inrush current to protect the power converter 14 from being damaged by instantaneous high inrush current.

The control circuit 10 may be configured to control operation states of the power converter 14 based on the input voltage V_{IN}. In an embodiment, the control circuit 10 may be configured to shut the power converter 14 down in occurrence of an abnormal event. The control circuit 10 may include an enable originate circuit 15, a time sequence protection circuit 20 and a driving control circuit 16. The enable originate circuit 15 may be configured to generate an enable signal EN at a low level when an over-voltage or under-voltage condition happens, i.e., when the input voltage V_{IN} is higher or lower than the working voltage range of the power converter 14. The enable signal EN is a time sequence signal indicative of turning-on/turning-off operations to be performed on the power converter 14. For example, the working voltage range of the power converter 14 may be 36V-60V. The enable originate circuit 15 may be configured to generate an enable signal EN at a high level in response to detecting that the input voltage V_{IN} is within the working voltage range, and to generate an enable signal EN at a low level in response to detecting that the input voltage is out of the working voltage range. The time sequence protection circuit 20 may be configured to generate a processed enable signal EN_{PRO} at an output pin based on the enable signal EN received from the enable originate circuit 15. In an embodiment of the present disclosure, the processed enable signal EN_{PRO} may increase continuously with a rising slope to an activated state when the enable signal EN transitions from a low level to a high level, and synchronously decreases to a deactivated state when the enable signal EN transitions from a high level to a low level. Details regarding the protection circuit 20 will be described below with respect to FIGS. 3-5. The driving control circuit 16 may be configured to generate driving signals based on the processed enable signal EN_{PRO}, so as to start the power converter 14 to work with the input voltage V_{IN} when the processed enable signal EN_{PRO} is at an activated state and to shut the power converter 14 down when the processed enable signal EN_{PRO} is at a deactivated state.

It is to be understood that the electronic device 1 shown in FIG. 2 is only for the purpose of illustration, without suggesting any limitation. As an alternative, the enable originate circuit 15 may be configured to generate the enable signal EN in other manners than comparing the input voltage V_{IN} with a predefined working voltage range. As another alternative, the enable signal EN may be input remotely or from other components and the enable originate circuit 15 may thus be omitted. As yet a further alternative, the driving control circuit 16 may be omitted and the time sequence protection circuit 20 may be configured to directly control the operation states of a controlled circuit.

FIG. 3 illustrates an example circuit implementation of a time sequence protection circuit 20 in accordance with a first embodiment of the present disclosure. As shown in FIG. 3, the time sequence protection circuit 20 comprises at least two input pins, e.g., a positive input pin and a negative input pin. The enable signal EN is determined based on the difference between the potential EN+ at the positive input pin and the potential EN− at the negative input pin. The negative input pin may be coupled to the ground GND1. The ground GND1 coupled to the negative input pin of the time sequence protection circuit 20 may be not commonly grounded to the common ground GND. The potential EN+ at the positive input pin and the potential EN− at the negative input pin may be affected due to interference.

In an embodiment, the time sequence protection circuit 20 comprises a first resistor R1, a first diode D1 and a capacitor C3 coupled in series between the positive input pin and the ground GND1. The first diode D1 has an anode terminal coupled to the first resistor R1 at a first node O and a cathode terminal coupled to the capacitor C3 at a second node P, thus providing a unidirectional current path from the positive input pin through the first resistor R1 and the first diode D1 to the capacitor C3. When the enable signal EN transitions from a low level (e.g., about 0 V) to a high level (e.g. about 8.0 V), the capacitor C3 may be continuously charged via the first resistor R1, such that the voltage across capacitor C3 continuously increases with a rising slope, and accordingly, the potential voltage at the first node O continuously increases.

In an embodiment, the time sequence protection circuit 20 may further comprise a second diode D2. The second diode D2 has an anode terminal coupled to the first node O and a cathode terminal coupled to the output pin of the time sequence protection circuit 20. The second diode D2 provides a unidirectional current path from the positive input pin through the first resistor R1 and the second diode D2 to the output pin. When the potential voltage at the first node O continuously increases due to charging of the capacitor C3, and after a potential difference between the first node O and the output pin reaches a threshold voltage of the second diode D2, the processed enable signal EN_{PRO} at the output pin continuously increases. For example, if the activation threshold of the driving control circuit 16 is 2.7 V, the driving control circuit 16 may not be effective when the processed enable signal EN_{PRO} is below 2.7 V and the driving control circuit 16 can maintain the power converter 14 off. After a delay time, when the capacitor C3 is charged to a relatively higher level, and accordingly the processed enable signal EN_{PRO} increases to 2.7V, the driving control circuit 16 may start the power converter 14 to work. The delay time of the processed enable signal EN_{PRO} may be determined based on the resistance of the first resistor R1 and the capacitance of the capacitor C3. In an embodiment, the delay time is associated with a coefficient Γ=R1*C3, wherein R₁ is the resistance value of the first resistor R1, C₃ is the capacitance value of the capacitor C3. The delay time may be adjusted in the range of 1 ms to 1 s according to actual needs.

In an embodiment, the time sequence protection circuit 20 may further comprise a third diode D3. The third diode D3 has an anode terminal coupled to the output pin of the time sequence protection circuit 20 and a cathode terminal coupled to the positive input pin of the time sequence protection circuit 20. The third diode D3 provides a unidirectional current path from the output pin through the third diode D3 to the positive input pin. By means of the third diode D3, the capacitor C2 coupled between the output pin and the common ground GND is discharged very quickly, and thus the processed enable signal EN_{PRO} may synchronously decrease to a low level when the enable signal EN transitions from a high level to a low level, thus achieving fast shutting-down of the power converter 14. This arrangement enables fast disable of the controlled circuit, which provides effective protection to the electronic device when an abnormal condition occurs.

In an embodiment, the time sequence protection circuit 20 may further comprise a fourth diode D4 coupled between the capacitor C3 and the positive input pin. The fourth diode D4 has an anode terminal coupled to the second node P and a cathode terminal coupled to the positive input pin, thus providing a unidirectional current path from the capacitor C3 through the fourth diode D4 to the positive input pin. When the enable signal EN transitions from a high level to a low level, the capacitor C3 may be discharged through the fourth diode D4, which may facilitate the normal start-up operation at a subsequent rising edge of the enable signal EN.

In an alternative embodiment, the time sequence protection circuit 20 may further comprise a third resistor R3 coupled between the fourth diode D4 and the positive input pin. This arrangement enables reducing the discharging current of the capacitor C3 when the enable signal EN transitions from a high level to a low level, thus protecting components at the front end of the time sequence protection circuit 20 from being damaged by the discharging current.

In some situations, in which, for example, the capacitance of the capacitor C3 (e.g., in the order of several microfarads) is much larger than the capacitance of the capacitor C2 (e.g., in the order of several nanofarads or several picofarads), the discharging of the capacitor C3 may be slower than that of the capacitor C2 coupled to the output pin when the enable signal EN transitions from a high level to a low level. The unidirectional current path provided by first diode D1 may prevent current flowing from the capacitor C3 to the output pin, thus guaranteeing the synchronous transition of the processed enable signal EN_{PRO} when the enable signal EN transitions from a high level to a low level.

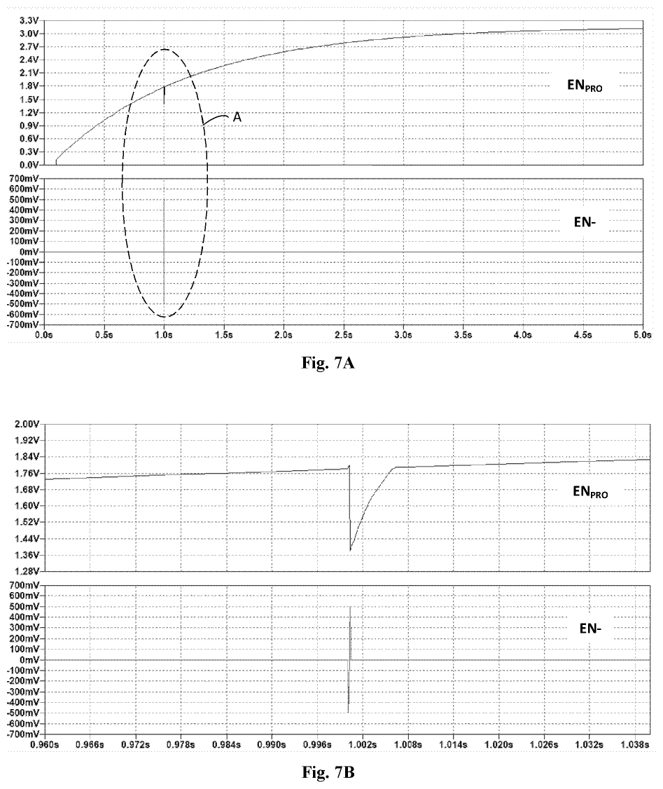

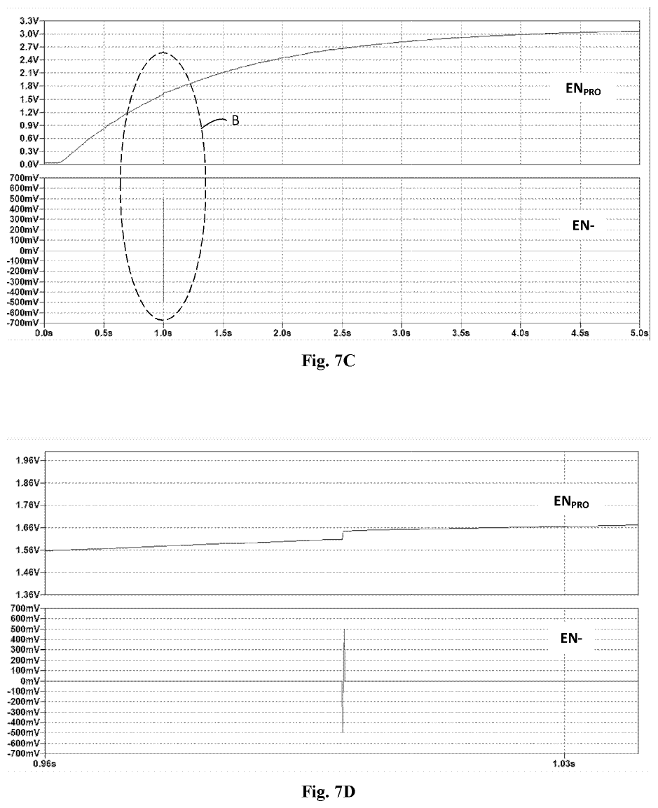

In an embodiment, when a positive interference is superimposed on the enable signal EN, the interference generated on the processed enable signal EN_{PRO} is reduced due to the voltage decrease across the first resistor D1. In an embodiment, when a negative interference is superimposed on the enable signal EN, the potential of the processed enable signal EN_{PRO} may be maintained or superimposed with a reduced interference than the negative interference since the second diode D2 prevents current flowing from the output pin to the first node O. With such arrangement, influence on the processed enable signal EN_{PRO} may be prevented or reduced in occurrence of interferences on the enable signal EN and the robustness of the processed enable signal EN_{PRO} may thus be enhanced by resisting interferences. Details regarding the anti-interference function of the time sequence protection circuit 20 will be described below with respect to FIGS. 7A-7D.

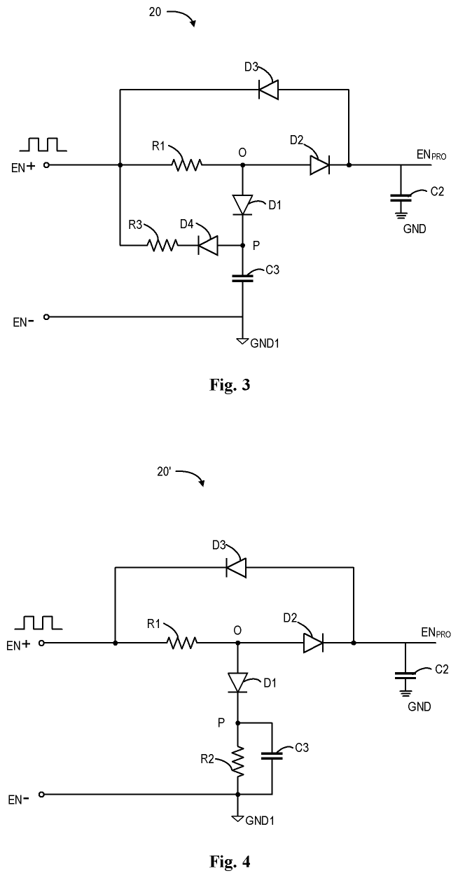

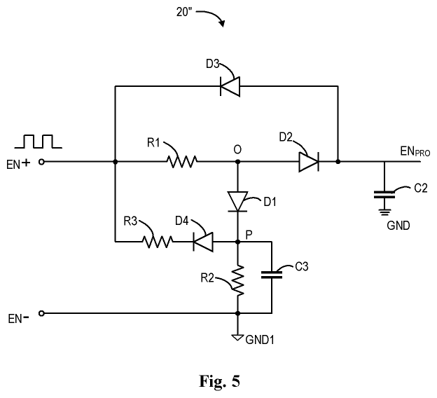

FIG. 4 illustrates an example circuit implementation of a time sequence protection circuit 20′ in accordance with a second embodiment of the present disclosure. The same reference numerals are used to denote the components described in FIG. 4 having the same structure as the components described in FIG. 3, and the description thereof will be omitted.

As shown in FIG. 4, the time sequence protection circuit 20′ may comprise a second resistor R2 coupled between the second node P and the negative input pin. The second resistor R2 provides a unidirectional current path from the capacitor C3 through the second node P and the second resistor R2 to the negative input pin. When the enable signal EN transitions from a high level to a low level, the capacitor C3 may be discharged through the second resistor R2, which may facilitate the normal start-up operation at a subsequent rising edge of the enable signal EN.

The activation delay time of the processed enable signal EN_{PRO} may be associated with a coefficient Γ′=(R₁//R₂)*C₃, wherein R₁ and R₂ are the resistance values of the first and second resistors R1 and R2 respectively, C₃ is the capacitance value of the capacitor C3 and R₁//R₂ is the parallel resistance value of the resistors R1 and R2. The ratio of resistance values of the resistors R1 and R2 may also be selected to adjust the processed enable signal EN_{PRO} by voltage-dividing enable signal EN.

FIG. 5 illustrates an example circuit implementation of a time sequence protection circuit 20″ in accordance with a third embodiment of the present disclosure. The same reference numerals are used to denote the components described in FIG. 5 having the same structure as the components described in FIGS. 3 and 4, and the description thereof will be omitted.

As shown in FIG. 5, the time sequence protection circuit 20″ may comprise the second resistor R2 coupled between the second node P and the negative input pin and the fourth diode D4 coupled between the capacitor C3 and the positive input pin. When the enable signal EN transitions from a high level to a low level, the capacitor C3 may be discharged through the current path provided by the second resistor R2 and the current path provided by the fourth diode D4, which may facilitate the normal start-up operation at a subsequent rising edge of the enable signal EN.

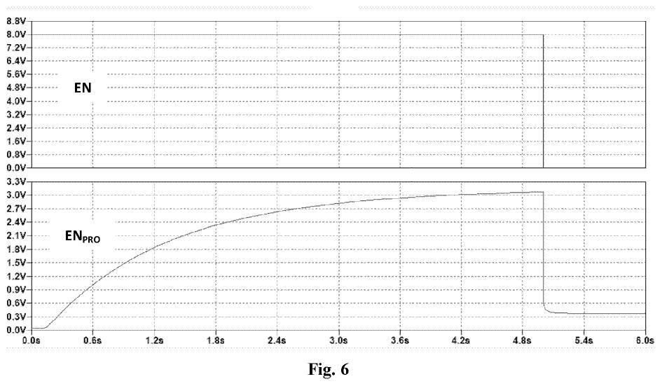

FIG. 6 illustrates graphical representations of measured waveforms of the input and output signals of the time sequence protection circuit in accordance with an embodiment of the present disclosure.

One example operational process of the time sequence protection circuit 20 can be divided into five stages according to the potential level of the input enable signal EN. For this particular example, the input enable signal EN may transition between a low level of 0 V and a high level of about 8.0 V, and the potential threshold of the processed enable signal EN_{PRO} for turning on the power converter 14 at the rear end of the time sequence protection circuit 20 may be about 2.7 V.

In a first operation stage, the input enable signal EN may be at a low level (e.g., 0V) and the processed enable signal EN_{PRO} is at a low level (e.g., 0V) synchronously.

In a second operation stage, the input enable signal EN may transition from a low level to a high level. At this stage, the capacitor C3 is charged by the input enable signal EN. The potential voltage at a first node O and thus the processed enable signal EN_{PRO} continuously increases. During the delay time, the processed enable signal EN_{PRO} is lower than the potential threshold of 2.7 V, and the power converter 14 may be kept off.

In a third operation stage, that is, after a delay time (e.g., 2.6 s as shown in FIG. 6) from the rising edge of the enable signal EN_{PRO}, the processed enable signal EN_{PRO} reaches the potential threshold of 2.7 V. The power converter 14 may be turned on.

In a fourth operation stage, the input enable signal EN is kept at a high level and the processed enable signal EN_{PRO} may keep rising until the capacitor C3 is fully charged. The power converter 14 is kept on at this stage.

In a fifth operation stage, the input enable signal EN may transition from a high level to a low level. At this stage, the capacitor C2 is discharged very quickly through the third diode D3, and thus the processed enable signal EN_{PRO} synchronously decreases to a low level. As a result, the power converter 14 may be turned off synchronously. Meanwhile, the capacitor C3 is discharged through the fourth diode D4 and/or the second diode R2. Since the capacitor C3 has a large capacitance, the discharging of the capacitor C3 may be slower than that of the capacitor C2, especially when the third resistor R3 is coupled between the fourth diode D4 and the positive input pin. The unidirectional current path provided by first diode D1 may prevent current flowing from the capacitor C3 to the output pin, thus guaranteeing the fast discharging of the capacitor C2 and thus the synchronous transition of the processed enable signal EN_{PRO} when the enable signal EN transitions from a high level to a low level.

FIG. 7A illustrates graphical representations of measured waveforms of the output signal of the time sequence protection circuit 20″ without the second diode D2 when interference occurs to the input enable signal EN and FIG. 7B illustrates an enlarged plot of measured waveforms in region A in FIG. 7A. The enable signal EN is determined based on the difference between the potential EN+ at the positive input pin and the potential EN− at the negative input pin. Accordingly, the negative interference superimposed on the potential EN− corresponds to a positive interference superimposed on the enable signal EN, and the positive interference superimposed on the potential EN− corresponds to a negative interference superimposed on the enable signal EN. As shown in FIG. 7B, a negative interference with a magnitude of 0.5V immediately followed with a positive interference with a magnitude of 0.5V arises on the potential EN− at the negative input pin at the instant of 1 s. A small positive interference is generated in the processed enable signal EN_{PRO} but then cancelled up by a sharp negative interference, and the processed enable signal EN_{PRO} drops from 1.78V to 1.38V.

FIG. 7C illustrates graphical representations of measured waveforms of the output signal of the time sequence protection circuit 20″ in FIG. 5 when interference occurs to the input enable signal EN; and FIG. 7D illustrates an enlarged plot of measured waveforms in region B in FIG. 7C. Interference superimposed on the enable signal EN in FIGS. 7C-7D is the same as in FIGS. 7A-7B. As shown in FIG. 7D, a small positive interference is generated in the processed enable signal EN_{PRO} in response to the large negative interference on the potential EN−; while no interference is generated in the processed enable signal EN_{PRO} in response to the large positive interference on the potential EN−.

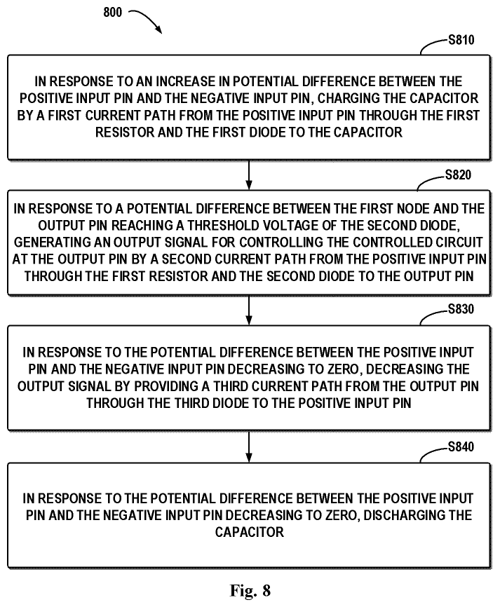

FIG. 8 illustrates a flow diagram of a method 800 for controlling a controlled circuit utilizing a time sequence protection module in accordance with an embodiment of the present disclosure.

At step S810, in response to an increase in potential difference between the positive input pin and the negative input pin, the capacitor C3 is charged by a first current path from the positive input pin through the first resistor R1 and the first diode D1 to the capacitor C3.

At step S820, in response to a potential difference between the first node O and the output pin reaching a threshold voltage of the second diode D2, an output signal (e.g., the 30) processed enable signal EN_{PRO}) for controlling the controlled circuit is generated at the output pin by a second current path from the positive input pin through the first resistor R1 and the second diode D2 to the output pin.

At step 830, in response to the potential difference between the positive input pin and the negative input pin decreasing to zero, the output signal is decreased by providing a third current path from the output pin through the third diode D3 to the positive input pin.

At step 830, in response to the potential difference between the positive input pin and the negative input pin decreasing to zero, the capacitor C3 is discharged by providing at least one of a fourth current path from the capacitor C3 through the fourth diode D4 to the positive input pin and a fifth current path from the capacitor C3 through a second resistor R2 to the negative input pin.

In an embodiment, in response to a positive interference superimposed on the input enable signal EN, the capacitor C3 in the first current path is charged, and the output signal is superimposed with a reduced interference than the positive interference.

In an embodiment, the third current path is a unidirectional current path. In response to a negative interference superimposed on the input enable signal EN, the potential of the processed enable signal EN_{PRO} is maintaining or superimposed with a reduced interference than the negative interference.

Embodiments of the present disclosure enable utilizing hardware peripheral circuit to control operation states of the controlled circuit. The circuit arrangement according to embodiments of the present disclosure can be easily implemented and do not require software control. Such arrangement enables flexible setting of a turning-on delay time and fast turning-off of the controlled circuit and can also resist interference superimposed on the input signal.

Various embodiments of the present disclosure have been described above and the above description is only exemplary rather than exhaustive and is not limited to the embodiments of the present disclosure. Many modifications and alterations, without deviating from the scope and spirit of the explained various embodiments, are obvious for those skilled in the art. The selection of terms in the text aims to best explain principles and actual applications of each embodiment and technical improvements made in the market by each embodiment, or enable those ordinary skilled in the art to understand embodiments of the present disclosure.

1. A time sequence protection circuit, comprising:
a first resistor coupled to a positive input pin of the time sequence protection circuit;
a first diode having an anode terminal coupled to the first resistor at a first node and a cathode terminal coupled to a second node;
a capacitor coupled between the second node and a negative input pin of the time sequence protection circuit;
a second diode having an anode terminal coupled to the first node and a cathode terminal coupled to an output pin of the time sequence protection circuit; and
a third diode having an anode terminal coupled to the output pin and a cathode terminal coupled to the positive input pin; and
at least one of:
a fourth diode having an anode terminal coupled to the second node and a cathode terminal coupled to the positive input pin, and
a second resistor coupled between the second node and the negative input pin.

2. The time sequence protection circuit of claim 1, wherein the time sequence protection circuit comprises the fourth diode and a third resistor coupled between the cathode terminal of the fourth diode and the positive input pin.

3. An electronic device, comprising:
a controlled circuit configured to be power supplied by an input voltage;
the time sequence protection circuit according to any of claim 1, configured to generate a processed enable signal at the output pin based on an enable signal, wherein the enable signal is a time sequence signal indicative of turn-on/turn-off operations to be performed on the controlled circuit; and
a driving control circuit configured to start the controlled circuit to work or shut the controlled circuit down based on the processed enable signal.

4. The electronic device of claim 5, further comprising an enable originate circuit, wherein the enable originate circuit is configured to generate the enable signal at a high level in response to detecting that the input voltage is within a working voltage range of the controlled circuit, and to generate the enable signal at a low level in response to detecting that the input voltage is out of the working voltage range.

5. A method for controlling a controlled circuit utilizing a time sequence protection module, wherein the time sequence protection module comprises:
a first resistor coupled to a positive input pin of the time sequence protection module;
a first diode having an anode terminal coupled to the first resistor at a first node and a cathode terminal coupled to a second node;
a capacitor coupled between the second node and a negative input pin of the time sequence protection module;
a second diode having an anode terminal coupled to the first node and a cathode terminal coupled to an output pin of the time sequence protection module; and
a third diode having an anode terminal coupled to the output pin and a cathode terminal coupled to the positive input pin;
wherein the method comprises:
in response to an increase in potential difference between the positive input pin and the negative input pin, charging the capacitor by a first current path from the positive input pin through the first resistor and the first diode to the capacitor;
in response to a potential difference between the first node and the output pin reaching a threshold voltage of the second diode, generating an output signal for controlling the controlled circuit at the output pin by a second current path from the positive input pin through the first resistor and the second diode to the output pin; and
in response to the potential difference between the positive input pin and the negative input pin decreasing to zero,
decreasing the output signal by providing a third current path from the output pin through the third diode to the positive input pin; and
discharging the capacitor by at least one of:
a fourth current path from the capacitor through a fourth diode to the positive input pin, wherein the fourth diode has an anode terminal coupled to the second node and a cathode terminal coupled to the positive input pin; and
a fifth current path from the capacitor through a second resistor to the negative input pin, wherein the second resistor is between the second node and the negative input pin.
